(19) United States
(12) Patent Application Publication
(10) Pub. No.: US 2009/0058352 A1
(43) Pub. Date: Mar. 5, 2009

(54) Cold storage device capable of collecting solar power

(75) Inventor: Wen-Chang Lin, Kaohsiung Hsien (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Yu Chuan Technology Enterprise Co., Ltd., Kaohsiung Hsien (TW)

(21) Appl. No.: 11/895,828

(22) Filed: Aug. 27, 2007

(51) Int. Cl. H02J 7/00; F25B 21/02; H02J 7/02; H01L 31/042

(52) U.S. Cl. 320/101; 62/3.62

(57) ABSTRACT

A cold storage device includes a rechargeable battery set disposed in an inner receiving space in a case body, a thermoelectric cooling unit mounted in the case body and connected electrically to the rechargeable battery set for cooling a cold storage space in the case body, a charging mode selecting unit operable so as to select one of electrical energy converted from solar power by a solar power collecting plate, DC power from an external DC power source, and DC power obtained by converting AC power from an external AC power source to charge the rechargeable battery set, and a power output selecting unit operable so as to output one of the electrical power from the rechargeable battery set and AC power obtained by converting the electrical power from the rechargeable battery set at a corresponding one of AC and DC output ports.

### BACKGROUND OF THE INVENTION

1. Field of the Invention

The invention relates to a cold storage device, more particularly to a cold storage device capable of collecting solar power.

2. Description of the Related Art

FIG. 1 illustrates a conventional storage box 3 that has a base body 31, and a cover body 32 connected pivotally to the base body 31 and cooperating with the base body 31 to define a storage space. In use, when food is placed in the conventional storage box 3 together with ice, the food in the storage space becomes cold as a result of the ice for a short period of time. However, even though the conventional storage box 3 can be used with ice, the conventional storage box 3 cannot maintain the storage space at a cold condition for a long period of time.

### SUMMARY OF THE INVENTION

Therefore, the object of the present invention is to provide a cold storage device that can collect solar power and that can supply electrical power to a load.

According to the present invention, a cold storage device comprises:

a case body configured with a battery-receiving space and a cold storage space therein, and having an outer surface;

a solar power collecting plate mounted on the outer surface of the case body and adapted to convert solar power into electrical energy;

a rechargeable battery set disposed in the battery-receiving space;

a thermoelectric cooling unit mounted in the case body and connected electrically to the rechargeable battery set for cooling the cold storage space;

a DC input port mounted on the outer surface of the case body and adapted to be connected electrically to an external direct current power source;

an AC input port mounted on the outer surface of the case body and adapted to be connected electrically to an external alternating current power source;

an AC-to-DC converter connected electrically to the AC input port and adapted to convert alternating current power from the alternating current power source into direct current power;

a charging mode selecting unit connected electrically to the solar power collecting plate, the DC input port, the AC-to-DC converter and the rechargeable battery set, the charging mode selecting unit being operable in a selected one of a first charging mode, where the direct current power from the AC-to-DC converter is used to charge the rechargeable battery set, a second charging mode, where direct current power from the external direct current power source is used to charge the rechargeable battery set, and a third charging mode, where the electrical energy from the solar power collecting plate is used to charge the rechargeable battery set;

a DC-to-AC converter connected electrically to the rechargeable battery set and converting electrical power from the rechargeable battery set into alternating current power;

an AC output port mounted on the outer surface of the case body;

a DC output port mounted on the outer surface of the case body; and

a power output selecting unit mounted on the outer surface of the case body, and connected electrically to the rechargeable battery set, the DC output port, the DC-to-AC converter and the AC output port, the power output selecting unit being operable in a selected one of a DC output mode, where the electrical power from the rechargeable battery set is outputted at the DC output port, and an AC output mode, where the alternating current power from the DC-to-AC converter is outputted at the AC output port.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional storage box;

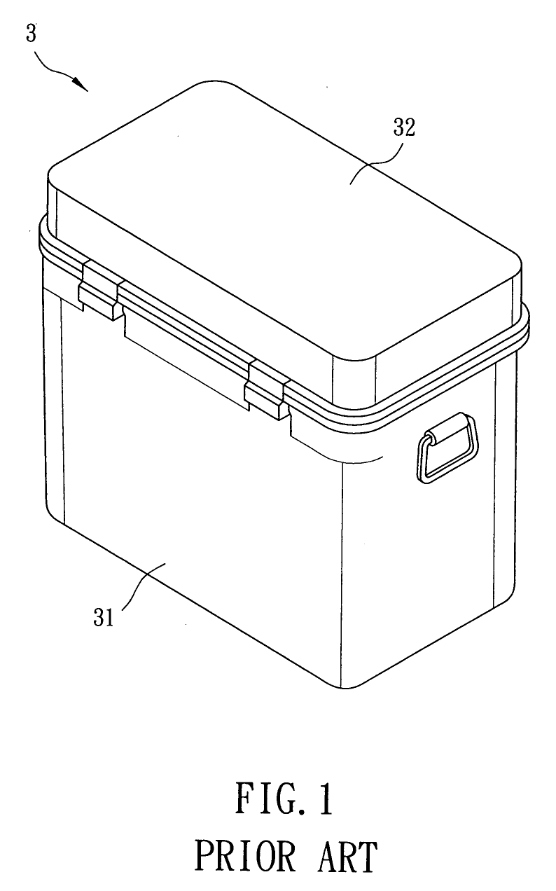

FIG. 2 is a perspective view showing the first preferred embodiment of a cold storage device according to the present invention;

FIG. 3 is a schematic circuit block diagram illustrating the first preferred embodiment; and

FIG. 4 is a perspective view showing the second preferred embodiment of a cold storage device according to the present invention.

### DETAILED DESCRIPTION OF THE PREFERRED EMBODIMENTS

Before the present invention is described in greater detail, it should be noted that like elements are denoted by the same reference numerals throughout the disclosure.

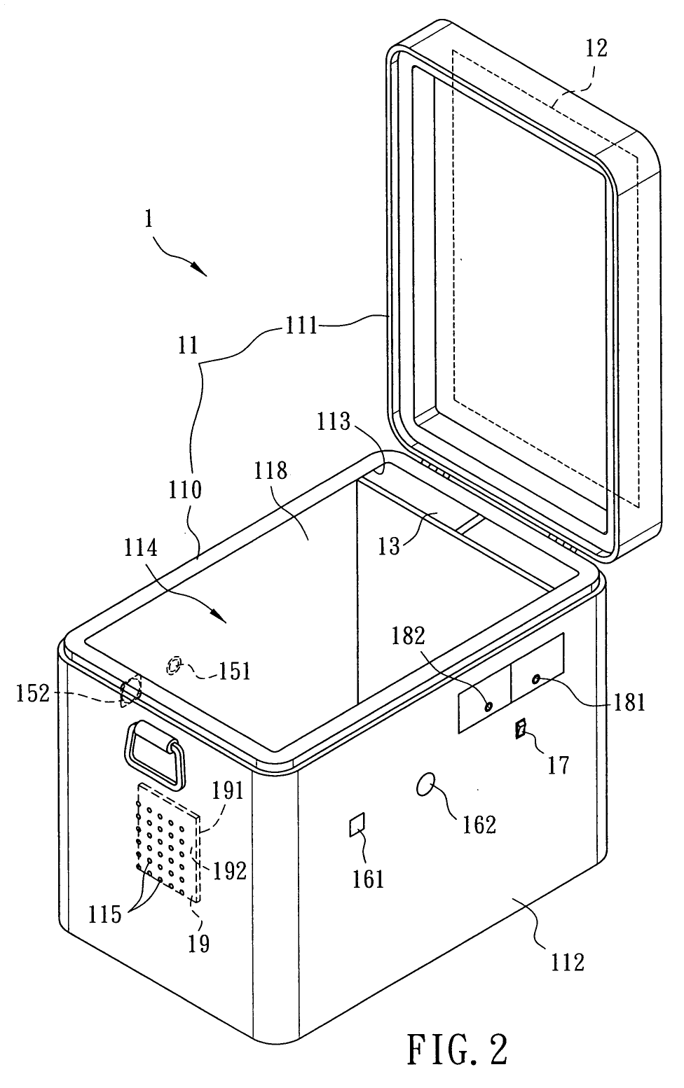

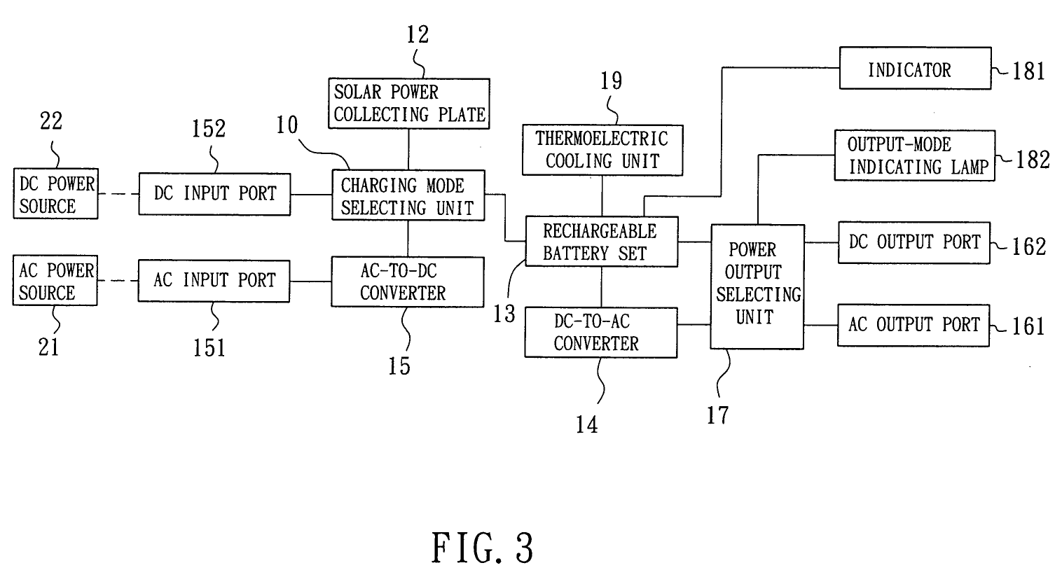

Referring to FIGS. 2 and 3, the first preferred embodiment of a cold storage device 1 according to the present invention is shown to include a case body 11, a solar power collecting plate 12, a rechargeable battery set 13, a thermoelectric cooling unit 19, a DC input port 152, an AC input port 151, an AC-to-DC converter 15, a charging mode selecting unit 10, a DC-to-AC converter 14, an AC output port 161, a DC output port 162, a power output selecting unit 17, an indicator 181, and an output-mode indicating lamp 182.

The case body 11 is configured with a battery-receiving space 113, and a cold storage space 114 therein, and has an outer surface 112. In this embodiment, the case body 11 consists of complementary lower and upper casing parts 110, 111 connected pivotally to each other. The cold storage space 114 is defined by an inner wall surface 118 of the case body 11.

The solar power collecting plate 12 is mounted on the outer surface 112 of the case body 11, and is adapted to convert solar power into electrical energy.

The rechargeable battery set 13 is disposed in the battery-receiving space 113 in the case body 11. In this embodiment, the rechargeable battery set 13 includes a lithium battery. In other embodiments, the rechargeable battery set 13 may include a nickel-hydrogen battery, a nickel-cadmium battery or a hydrocarbon battery.

The thermoelectric cooling unit 19 is mounted in the lower casing part 110 of the case body 11, and is connected electrically to the rechargeable battery set 13 for cooling the cold storage space 114. In this embodiment, the thermoelectric cooling unit 19 is disposed between the inner wall surface 118 and the outer surface 112 of the case body 11, and has a cold side 191 disposed adjacent to the inner wall surface 118, and a hot side 192 opposite to the cold side 191 and disposed adjacent to the outer surface 112. It is noted that the outer surface 112 of the case body 11 is formed with a plurality of heat-dissipating holes 115 disposed adjacent to the thermoelectric cooling unit 19 for dissipating heat from the hot side 192 of the thermoelectric cooling unit 19. Since the feature of the invention does not reside in the configuration of the thermoelectric cooling unit 19, which is conventional, details of the same are omitted herein for the sake of brevity.

The DC input port 152 is mounted on the outer surface 112 of the case body 11, and is adapted to be connected electrically to an external direct current (DC) power source 22.

The AC input port 151 is mounted on the outer surface 112 of the case body 11, and is adapted to be connected electrically to an external alternating current (AC) power source 21.

The AC-to-DC converter 15 is connected electrically to the AC input port 151, and is adapted to convert AC power from the AC power source 21 into DC power.

The charging mode selecting unit 10 is connected electrically to the solar power collecting plate 12, the DC input port 152, the AC-to-DC converter 15 and the rechargeable battery set 13. The charging mode selecting unit 10 is operable in a selected one of a first charging mode, where the DC power from the AC-to-DC converter 15 is used to charge the rechargeable battery set 13, a second charging mode, where DC power from the external DC power source 22 is used to charge the rechargeable battery set 13, and a third charging mode, where the electrical energy from the solar power collecting plate 12 is used to charge the rechargeable battery set 13.

The DC-to-AC converter 14 is connected electrically to the rechargeable battery set 13, and converts electrical power from the rechargeable battery set 13 into AC power.

The AC output port 161 is mounted on the outer surface 112 of the case body 11.

The DC output port 162 is mounted on the outer surface 112 of the case body 11.

The power output selecting unit 17 is mounted on the outer surface 112 of the case body 11, and is connected electrically to the rechargeable battery set 13, the DC output port 162, the DC-to-AC converter 14 and the AC output port 161. The power output selecting unit 17 is operable in a selected one of a DC output mode, where the electrical power from the rechargeable battery set 13 is outputted at the DC output port 162, and an AC output mode, where the AC power from the DC-to-AC converter 14 is outputted at the AC output port 161.

The indicator 181 is mounted on the outer surface 112 of the case body 11 for indicating amount of the electrical power stored in the rechargeable battery set 13. In this embodiment, the indicator 181 includes an indicating lamp activated to emit light when the electrical power stored in the rechargeable battery set 13 is exhausted.

The output-mode indicating lamp 182 is mounted on the outer surface 112 of the case body 11, and is activated to emit light when the power output selecting unit 17 is switched to the AC output mode.

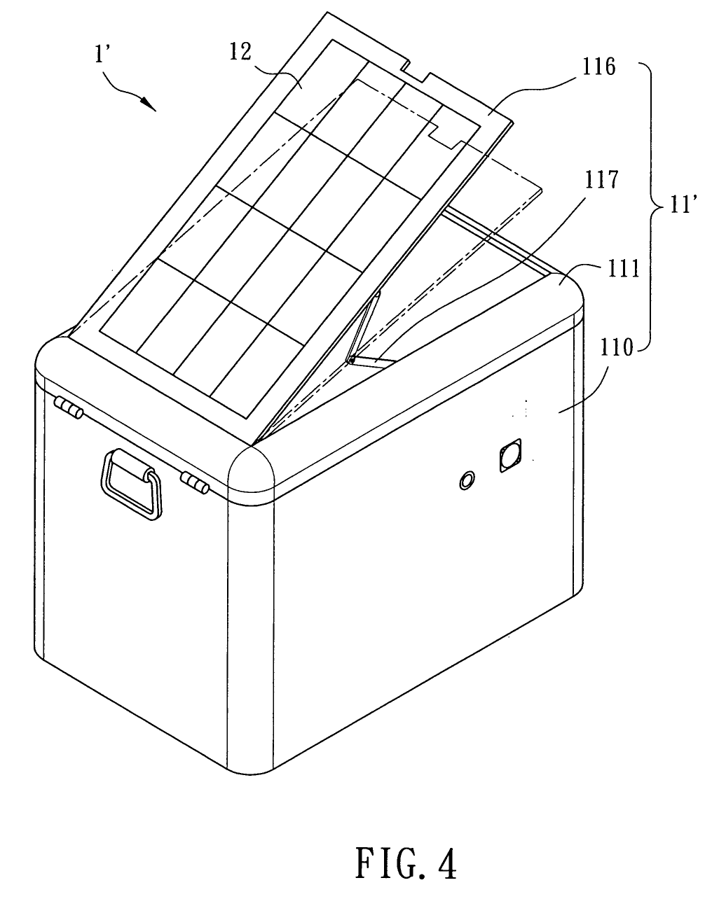

FIG. 4 illustrates the second preferred embodiment of a cold storage device 1′ according to this invention, which is a modification of the first preferred embodiment. Unlike the previous embodiment, the case body 11′ further includes a support plate 116 and a positioning member. The support plate 116 is disposed on and is connected pivotally to a top side of the upper casing part 111, and is mounted with the solar power collecting plate 12. The positioning member includes two retractable pivot rods 117 (only one is shown) each interconnecting the support plate 116 and the upper casing part 111 for positioning the support plate 116 at a desired tilting angle so as to permit effective collection of solar power.

In sum, aside from being capable of collecting solar power, since the case body 11 is portable, the cold storage device 1, 1′ of this invention facilitates outdoor use. Moreover, the cold storage device 1, 1′ can serve as a power supply for supplying electrical power to a load via one of the AC output port 161 and the DC output port 162.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A cold storage device comprising:
a case body configured with a battery-receiving space and a cold storage space therein, and having an outer surface;
a solar power collecting plate mounted on said outer surface of said case body and adapted to convert solar power into electrical energy;
a rechargeable battery set disposed in said battery-receiving space;
a thermoelectric cooling unit mounted in said case body and connected electrically to said rechargeable battery set for cooling said cold storage space;
a DC input port mounted on said outer surface of said case body and adapted to be connected electrically to an external direct current power source;
an AC input port mounted on said outer surface of said case body and adapted to be connected electrically to an external alternating current power source;
an AC-to-DC converter connected electrically to said AC input port and adapted to convert alternating current power from the alternating current power source into direct current power;
a charging mode selecting unit connected electrically to said solar power collecting plate, said DC input port, said AC-to-DC converter and said rechargeable battery set, said charging mode selecting unit being operable in a selected one of a first charging mode, where the direct current power from said AC-to-DC converter is used to charge said rechargeable battery set, a second charging mode, where direct current power from the external direct current power source is used to charge said rechargeable battery set, and a third charging mode, where the electrical energy from said solar power collecting plate is used to charge said rechargeable battery set;
a DC-to-AC converter connected electrically to said rechargeable battery set and converting electrical power from said rechargeable battery set into alternating current power;
an AC output port mounted on said outer surface of said case body;
a DC output port mounted on said outer surface of said case body; and
a power output selecting unit mounted on said outer surface of said case body, and connected electrically to said rechargeable battery set, said DC output port, said DC-to-AC converter and said AC output port, said power output selecting unit being operable in a selected one of a DC output mode, where the electrical power from said rechargeable battery set is outputted at said DC output port, and an AC output mode, where the alternating current power from said DC-to-AC converter is outputted at said AC output port.

2. The cold storage device as claimed in claim 1, wherein said case body has an inner wall surface defining said cold storage space, said thermoelectric cooling unit being disposed between said inner wall surface and said outer surface of said case body, and having a cold side disposed adjacent to said inner wall surface of said case body, and a hot side opposite to said cold side and disposed adjacent to said outer surface of said case body.

3. The cold storage device as claimed in claim 2, wherein said outer surface of said case body is formed with a plurality of heat-dissipating holes for dissipating heat from said hot side of said thermoelectric cooling unit.

4. The cold storage device as claimed in claim 1, further comprising an indicator mounted on said outer surface of said case body for indicating amount of the electrical power stored in said rechargeable battery set.

5. The cold storage device as claimed in claim 4, wherein said indicator includes an indicating lamp activated to emit light when the electrical power stored in said rechargeable battery set is exhausted.

6. The cold storage device as claimed in claim 1, further comprising an output-mode indicating lamp mounted on said outer surface of said case body and activated to emit light when said power output selecting unit is switched to the AC output mode.

7. The cold storage device as claimed in claim 1, wherein said rechargeable battery set is selected from the group consisting of a nickel-hydrogen battery, a nickel-cadmium battery, a lithium battery and a hydrocarbon battery.

8. The cold storage device as claimed in claim 1, wherein said case body includes:
complementary lower and upper casing parts connected pivotally to each other;
a support plate disposed on and connected pivotally to a top side of said upper casing part, and mounted with said solar power collecting plate; and
a positioning member interconnecting said support plate and said upper casing part for positioning said support plate at a desired tilting angle.
